(19) United States
(12) Patent Application Publication
(10) Pub. No.: US 2025/0274132 A1
(43) Pub. Date: Aug. 28, 2025

(54) MIXED SIGNAL ELECTRONICS FOR LOCKING CONTROL OF HIGH-Q FEEDBACK LOOPS AND ASSOCIATED CIRCUITRY FOR DETECTING PHASE SHIFT OF A RESONATOR

(71) Applicant: Panasonic Corporation of North America, Newark, NJ (US)

(72) Inventors: Mohammad Maymandi Nejad, Waltham, MA (US); Chechuan Che, Waltham, MA (US); Yaesuk Jeong, Waltham, MA (US)

(21) Appl. No.: 19/061,391

(22) Filed: Feb. 24, 2025

Related U.S. Application Data
(60) Provisional application No. 63/556,998, filed on Feb. 23, 2024.

(51) Int. Cl. H03L 7/093

(52) U.S. Cl. CPC H03L 7/093

(57) ABSTRACT

Circuits for controlling the output of a frequency resonator, specifically for adjusting the output based upon changes in operational parameters such as changes in temperature, are provided. For example, a circuit can include a time-to-digital convertor (TDC) loop configured to be locked to a reference signal and a lock range control (LRC) circuit operably coupled to the TDC loop, the LRC circuit including a sensor and a limiter. The limiter is configured to provide LRC input signal to divider circuitry such that an output of the TDC loop stays close to a resonant value of the reference signal. An alternate circuit can include an integrator circuit path to generate an output signal having an output frequency and a delay loop configured to adjust a reference signal frequency, the delay loop including a delay element configured to offset a phase of the reference signal based upon an initial calibration.

### CROSS-REFERENCE TO RELATED APPLICATION

The present application claims the benefit of U.S. Provisional Patent Application No. 63/556,998, filed Feb. 23, 2024, the disclosure of which is hereby incorporated by reference in its entirety for all purposes.

### FIELD OF THE INVENTION

The present disclosure relates to the field of feedback loops and associated circuitry for maintaining resonant frequency in a feedback loop to produce a constant clock signal.

### BACKGROUND

A high-Q system refers to a system with a high associated Q-factor which, in physics, indicates a system's ability to store energy relative to the energy it dissipates over a single oscillation cycle. Thus, essentially, a high-Q system can resonate at a specific frequency for an extended time period with minimal energy loss.

Feedback loops can be used for high-precision timing circuits that result in the locking of two high-Q systems when sharing a common reference timing signal. However, changes in operational conditions can cause various components within timing circuits to perform at changing frequencies, resulting in the two high-Q systems falling out of synchronization.

### SUMMARY

In at least one example as described herein, a circuit for controlling the output of a frequency resonator is provided. The circuit includes a time-to-digital convertor (TDC) loop configured to be locked to a reference signal. The circuit further includes a lock range control (LRC) circuit operably coupled to the TDC loop, the LRC circuit including a sensor and a limiter, wherein the limiter is configured to provide LRC input signal to signal divider circuitry such that an output of the TDC loop stays close to a resonant value of the reference signal.

Implementations of the circuit for controlling the output of a frequency resonator can include one or more of the following features.

In some examples of the circuit for controlling the output of a frequency resonator, the LRC input signal can include a temperature-dependent signal. In some further examples, the sensor includes a temperature sensor. In some further examples, the LRC circuit includes a conditioning circuit to filter the output of the temperature sensor; and an analog to digital converter to convert an output of the conditioning circuit to a digital signal for processing by the signal divider circuitry.

In some examples of the circuit for controlling the output of a frequency resonator, the limiter is configured to operate at a frequency range such that an output of the limiter is within an acceptable input range of the signal divider circuitry.

In some examples of the circuit for controlling the output of a frequency resonator, the circuit includes a high-Q circuit configured to resonate at a specific frequency with minimal energy loss over time.

In at least one example as describe herein, a circuit for adjusting signal frequency based upon changes in operational parameters is provided. The circuit includes an integrator circuit path configured to generate an output signal having an output frequency. The circuit further includes a delay locked loop configured to adjust a reference signal frequency, the delay locked loop including a delay element that is configured to offset a phase of the reference signal based upon an initial calibration such that the reference signal frequency matches the output frequency of the output signal.

Implementations of the circuit for adjusting signal frequency based upon changes in operational parameters can include one or more of the following features.

In some examples of the circuit for adjusting signal frequency based upon changes in operational parameters, the integrator circuit path comprises buffering and filtering circuitry to remove any harmonics from the reference signal.

In some examples of the circuit for adjusting signal frequency based upon changes in operational parameters, the circuit is further configured to adjust signal frequency based upon changes in operational temperature. In some examples, the delay element is further configured to offset the phase of the reference signal based upon an initial temperature-based circuit calibration.

In some examples of the circuit for adjusting signal frequency based upon changes in operational parameters, the output signal of the integrator circuit path and the calibrated reference signal are combined to produce a switched current output signal.

In some examples of the circuit for adjusting signal frequency based upon changes in operational parameters, the circuit includes a high-Q circuit configured to resonate at a specific frequency with minimal energy loss over time.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and are incorporated in and constitute a part of this specification but are not intended as a definition of the limits of any particular example. The drawings, together with the remainder of the specification, serve to explain principles and operations of the described and claimed aspects. In the figures, each identical or nearly identical component that is illustrated in various figures is represented by a like numeral. For purposes of clarity, not every component may be labeled in every figure.

FIG. 1 illustrates an example architecture for a high-precision timing circuit, in accordance with at least one embodiment as described herein.

FIG. 2 illustrates an example architecture for a lock range control mechanism, in accordance with at least one embodiment as described herein.

FIG. 3 illustrates the operational range of a limiter for a lock range control mechanism, in accordance with at least one embodiment as described herein.

FIG. 4 illustrates a clock circuit including an integrator and delay locked loop, in accordance with at least one embodiment as described herein.

### DETAILED DESCRIPTION

The present disclosure is directed to generating timing and/or clock signals and maintaining resonant frequency during operation of a circuit, for example, a high-Q system as described herein. Any potential changes in operational conditions can result in a change to the circuit's resonant frequency and, thus, a change to the overall output of the timing circuitry. For example, during operation, a change to the operational temperature of one or more components within the circuit may result in a potential change to the overall output of the complete circuit due to physical changes of the materials within the components resulting from the change in temperature.

The systems, processes, and circuits as described herein are designed to accommodate for changes in operational conditions while maintaining high-Q levels of operation of timing circuits.

Examples of the systems, processes, and circuits discussed herein are not limited in application to the details of construction and the arrangement of components set forth in the following description or illustrated in the accompanying drawings. The methods and systems are capable of implementation in other examples and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

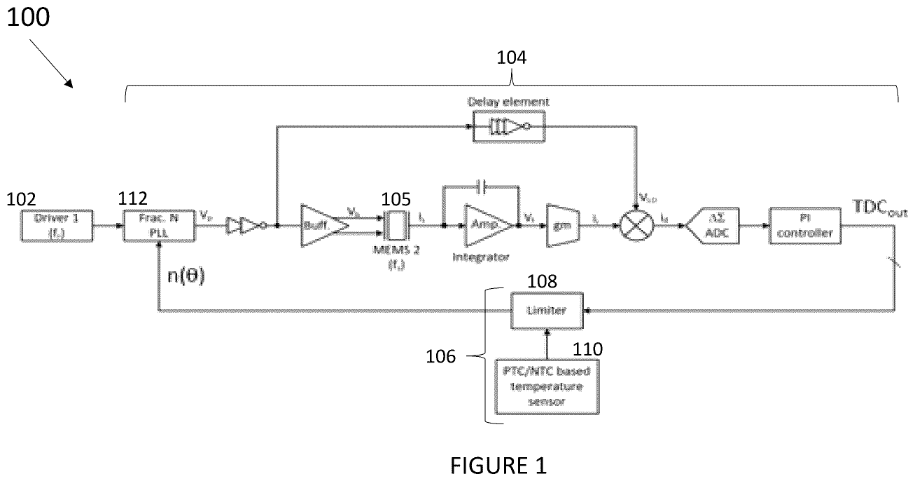

FIG. 1 illustrates a sample architecture of a high precision timing circuit 100. This circuit 100 includes a reference oscillator 102 configured to generate a high-stability sine wave signal to be used, for example, as an output reference signal. The frequency of this reference oscillator is based upon a high-Q microelectromechanical system (MEMS) device. However, during operation, the frequency of this oscillator 102 can change slightly with changes in temperature.

As further shown in FIG. 1, the reference signal is applied to a time-to-digital converter (TDC) loop 104 which contains another high-Q MEMS device 105. To operate properly, the TDC loop 104 should always be locked to the reference signal. Since the quality factors of the two MEMS used in this circuit are very high, any slight frequency shift in each of the two MEMS will cause the TDC loop 104 to get out of lock with the reference signal. If the two loops become unlocked, it will take time to return to the lock state again, and there is always a chance that the lock condition will never be met.

To guarantee the TDC loop 104 stays locked with the reference signal, a lock range control (LRC) mechanism 106 can be added to the TDC loop 104. This LRC mechanism can include a temperature sensor 108 and a limiter 110 that limits the input to the fractional N PLL 112.

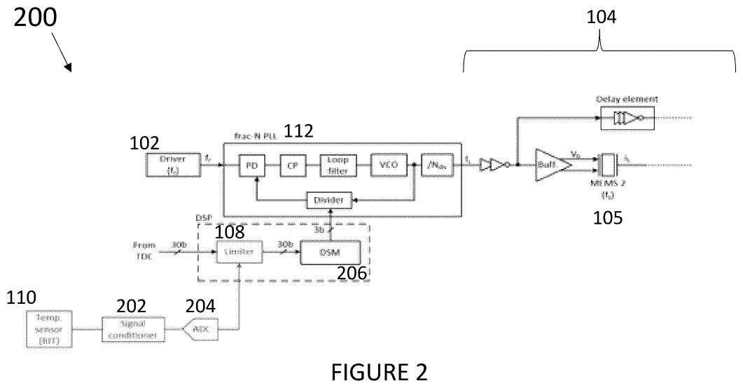

FIG. 2 shows an example circuit view 200 illustrating the LRC mechanism 106 as shown in FIG. 1 in more detail. During operation of the LRC mechanism 106, when the circuit is powered up, the TDC loop will not be locked to the reference signal because the output frequency of the frac-N PLL 112 is not within the bandwidth of the TDC MEMS 105. Since the Q of the TDC MEMS 105 is very high, a slight frequency shift makes the output of the TDC MEMS very small, hence, the loop gain may drop below 1 which means the TDC loop 104 will never settle. Even if the loop gain is more than 1, it may take a long time for the TDC loop 104 to settle and lock to the reference signal.

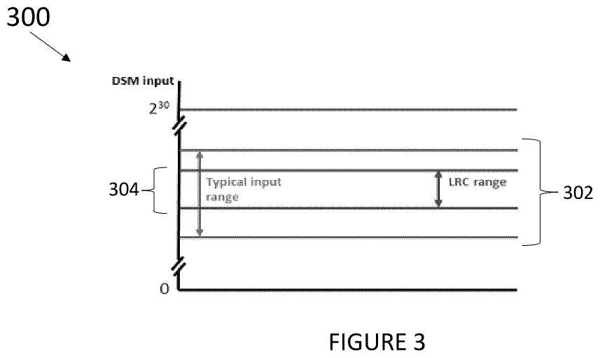

To avoid this happening, a limiter 108 can be used to limit the input going into the frac-N PLL divider 112 (see the sample limiter operational range as shown in FIG. 3). In this way, the frequency of the signal going into the TDC MEMS 105 can be configured to remain close to its resonant value (e.g., the value of the reference signal as provided by reference oscillator 102). This helps the TDC loop 104 to settle at the reference signal frequency after powering up or if the lock condition is lost during normal operation.

In certain implementations, the two high and low thresholds of the limiter 108 can be temperature dependent. Hence, a temperature sensor 110 can be used, and the temperature is measured and digitized. In certain implementations, the limiter 108 can be processed in the digital domain and any correction can be applied digitally. For example, if there is any curvature in the characteristic of the TDC MEMS 105, it can be reduced by applying a polynomial curve fitting.

As further shown in FIG. 2, additional components can be included in the LRC mechanism such as a signal conditioner 202, an analog to digital converter (ADC) 204, and a dynamic saturation modeling (DSM) component 206. As described herein, the output of the temperature sensor 110 can be converted to a digital signal for further processing. Prior to conversion, the output of the temperature sensor 110 can be conditioned by the signal conditioner 202 to, for example, filter the signal to remove noise or any other unwanted portions of the output of the temperature sensor. The conditioned signal can then be converted to a digital signal by ADC 204. The converted digital signal can then be passed to the limiter 108 for further processing in concert with the DSM 206.

FIG. 3 illustrates an example operational range graph 300 for various circuit components as described herein. As specifically shown in FIG. 3, the input of the frac-N PLL 112 can have a specific range 302. The output of the limiter (e.g., limiter 108) can be configured such that it has a specific range 304. As shown in FIG. 3, range 304 falls completely within range 302 and, as such, the output of the limiter 108 can be configured such that it is within the acceptable input range of the frac-N PLL 112.

As described herein, when circuitry temperature changes, the resonant frequency of a resonator can shift as a result of the temperature change. By driving the resonator with a clock centered at its resonant frequency, the resonant frequency change incurs a phase change corresponding to the temperature changes. In certain implementations, this phase change can be detected by mixing the driven clock with the electronic current that flows out of the resonator after it is processed through an electronic integrator. The integrator is converted to current via a gm cell, and the current is switched by the driven clock. The DC component of the mixing represents the phase change.

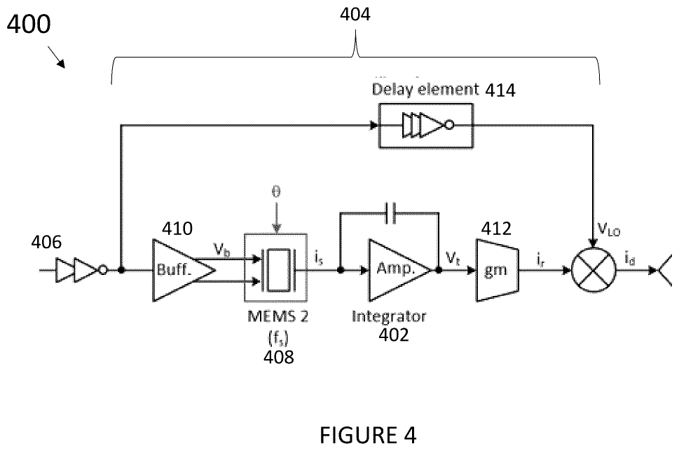

FIG. 4 illustrates a sample circuit 400 including an integrator 402 and a delay locked loop 404 for adjusting frequency based upon changes in operational parameters such as operational temperature. In the circuit as shown in FIG. 4, signal clk 406 can be locked to the resonant frequency of MEMS 408 at, for example, 41 MHz (fs). This clock can be buffered by a high-bandwidth open-loop amplifier 410 and drive MEMS 408. MEMS 408, being a high-Q device with limited bandwidth, can filter out the harmonics of clk 406.

In certain implementations, signal is, as shown in FIG. 4, can be a sinusoidal signal (e.g., as output by a reference oscillator as described above in the description of FIGS. 1 and 2). When the operational temperature of the circuit 400, or any individual component within the circuit, varies, the resonant frequency of MEMS 408 can shift accordingly. Depending upon on the magnitude of the frequency shift, this change of resonant frequency can cause signal iₛ to move out of phase with respect to V_{b}. In certain implementations, the phase of signal iₛ can shift by 90° after passing through the integrator 402. The signal at Vₜ can be a voltage signal. The signal can then be converted to signal iᵣ via a gm-cell 412. For example, the gm-cell 412 can be configured to convert the input voltage signal Vt. to output current signal iᵣ by passing the input signal through one or more passive resistors.

In some examples, V_{LO} can be a square-wave clock running at the same frequency as the input clk 406. The following equation shows the relationship assuming V_{LO} is sinusoidal signal with amplitude of V_{A}. The simplification is valid since the harmonics of mixing of V_{LO} and iᵣ will be filtered out before the ADC converter:

$${V}_{A} \cdot sin ( ω t ) \times {i}_{r} \cdot cos ( ω t + θ ) = \frac{1}{2} {V}_{A} \cdot {i}_{r} [ sin ( 2 ω t + θ ) - sin ( θ ) ]$$

This equation can represent the front-end gain of the phase detector which is high based on the Q of the resonator. Signal i_{d} is the switched current which is then filtered and digital converted in baseband to obtain the phase information.

Because the circuit 400 is processing relatively high-frequency signals, the delay through the various sense path blocks becomes temperature dependent. This issue is alleviated by having a delay element 414 that can be calibrated to ensure that the systematic phase offset between iᵣ and V_{LO} are set properly during a temperature-controlled initial calibration. Another implementation of the delay element 414 is via a DLL (Delay-locked-loop) such that V_{LO} does not vary with respect to input clk 406. In addition, the circuit 400 can be automatically calibrated via a PTAT-based DLL in the delay element 414 to further alleviate the temperature dependence of difference in phase between the two electronic paths. The nonlinearity of the sensing path phase delay with respect to temperature is dominated by MEMS 408 linearity instead of the circuit linearity.

It should be noted that temperature-dependent calibration and resonant frequency adjustment as described above is provided by way of example only. In certain implementations, changes to additional operational parameters of the circuitry and the individual circuitry components can be measured and accounted for. For example, additional changes in environmental parameters such as changes in humidity may be measured and accounted for. Similarly, physical operation parameters such as operational vibration or other movements of the circuitry and related components can be measured for calibration and adjustment during operation.

Having thus described several aspects of at least one example, it is to be appreciated that various alterations, modifications, and improvements will readily occur to those skilled in the art. For instance, examples disclosed herein can also be used in other contexts. Such alterations, modifications, and improvements are intended to be part of this disclosure and are intended to be within the scope of the examples discussed herein. Accordingly, the foregoing description and drawings are by way of example only.

Also, the phraseology and terminology used herein is for the purpose of description and should not be regarded as limiting. Any references to examples, components, elements or acts of the systems and methods herein referred to in the singular can also embrace examples including a plurality, and any references in plural to any example, component, element or act herein can also embrace examples including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” can be construed as inclusive so that any terms described using “or” can indicate any of a single, more than one, and all of the described terms. In addition, in the event of inconsistent usages of terms between this document and documents incorporated herein by reference, the term usage in the incorporated references is supplementary to that of this document; for irreconcilable inconsistencies, the term usage in this document controls.

We claim as follows:

1. A circuit for controlling the output of a frequency resonator, the circuit comprising:
a time-to-digital convertor (TDC) loop configured to be locked to a reference signal; and
a lock range control (LRC) circuit operably coupled to the TDC loop, the LRC circuit comprising a sensor and a limiter, wherein the limiter is configured to provide LRC input signal to signal divider circuitry such that an output of the TDC loop stays close to a resonant value of the reference signal.

2. The circuit of claim 1, wherein the LRC input signal comprises a temperature-dependent signal.

3. The circuit of claim 2, wherein the sensor comprises a temperature sensor.

4. The circuit of claim 3, wherein the LRC circuit further comprises:
a conditioning circuit to filter the output of the temperature sensor; and
an analog to digital converter to convert an output of the conditioning circuit to a digital signal for processing by the signal divider circuitry.

5. The circuit of claim 1, wherein the limiter is configured to operate at a frequency range such that an output of the limiter is within an acceptable input range of the signal divider circuitry.

6. The circuit of claim 1, wherein the circuit comprises a high-Q circuit configured to resonate at a specific frequency with minimal energy loss over time.

7. A circuit for adjusting signal frequency based upon changes in operational parameters, the circuit comprising:
an integrator circuit path configured to generate an output signal having an output frequency; and
a delay locked loop configured to adjust a reference signal frequency, the delay locked loop comprising a delay element that is configured to offset a phase of the reference signal based upon an initial calibration such that the reference signal frequency matches the output frequency of the output signal.

8. The circuit of claim 7, wherein the integrator circuit path comprises buffering and filtering circuitry to remove any harmonics from the reference signal.

9. The circuit of claim 7, wherein circuit is further configured to adjust signal frequency based upon changes in operational temperature.

10. The circuit of claim 9, wherein the delay element is further configured to offset the phase of the reference signal based upon an initial temperature-based circuit calibration.

11. The circuit of claim 7, wherein the output signal of the integrator circuit path and the calibrated reference signal are combined to produce a switched current output signal.

12. The circuit of claim 7, wherein the circuit comprises a high-Q circuit configured to resonate at a specific frequency with minimal energy loss over time.
